(19) United States
(12) Patent Application Publication
(10) Pub. No.: US 2025/0142776 A1
(43) Pub. Date: May 1, 2025

(54) COOLING MEDIUM DISTRIBUTION APPARATUS, HEAT DISSIPATION CABINET, AND SERVER SYSTEM

(71) Applicant: xFusion Digital Technologies Co., Ltd., Zhengzhou (CN)

(72) Inventors: Hui Jia, Zhengzhou (CN); Guangjing Wang, Zhengzhou (CN)

(21) Appl. No.: 19/004,026

(22) Filed: Dec. 27, 2024

Related U.S. Application Data
(63) Continuation of application No. PCT/CN2023/109426, filed on Jul. 26, 2023.

(30) Foreign Application Priority Data
Aug. 3, 2022 (CN) 202210940484.2

(51) Int. Cl. H05K 7/20

(52) U.S. Cl. CPC H05K 7/20327; H05K 7/20318; H05K 7/20818

(57) ABSTRACT

The cooling medium distribution apparatus includes a first heat exchanger, a second heat exchanger, a liquid storage tank, and a delivery pump. An input end of the first runner is configured to allow a gaseous first cooling medium to flow in, and an output end of the first runner is in communication with an input end of the liquid storage tank. An output end of the liquid storage tank is configured to be in communication with an input end of the delivery pump, and an output end of the delivery pump is configured to allow a liquid first cooling medium to flow out. The second runner is used for flowing of a second cooling medium to exchange heat with the first cooling medium in the first runner. The second heat exchanger enables the second cooling medium in the third runner to exchange heat with the first cooling medium.

### CROSS-REFERENCE TO RELATED APPLICATIONS

This application is a continuation of International Application No. PCT/CN2023/109426, filed on Jul. 26, 2023, which claims priority to Chinese Patent Application No. 202210940484.2, filed with the China National Intellectual Property Administration on Aug. 3, 2022, both of which are hereby incorporated by reference in its entirety.

### TECHNICAL FIELD

Embodiments of this application relate to the field of liquid cooling heat dissipation technologies, and in particular, to a cooling medium distribution apparatus, a heat dissipation cabinet, and a server system.

### BACKGROUND

An Internet service provider, an enterprise platform, a research institution, and the like all have a large quantity of computing needs, and a work platform that bears needs such as storage, computing, and a network is referred to as a data center. In addition, with an increasing demand for information and communication technologies in the modern society, the data center is also rapidly developed, and therefore, information and communication technology (ICT) devices in the data center gradually develop from low density to high density. ICT devices of high density generate a large amount of heat during running. Therefore, a cooling system needs to be disposed in the data center, to ensure normal running of the ICT devices in the data center.

In a related technology, a vaporized cooling medium is generated in a two-phase heat dissipation process of an electronic device in a server system. The vaporized cooling medium enters a cooling medium distribution apparatus, and a condenser of the cooling medium distribution apparatus condenses the vaporized cooling medium into a liquid cooling medium. However, the condenser needs to work in a negative pressure state to change the vaporized cooling medium into the liquid cooling medium. However, when the size of the condenser is large, the processing difficulty of the condenser is correspondingly increased.

### SUMMARY

Embodiments of this application provide a cooling medium distribution apparatus, a heat dissipation cabinet, and a server system. The cooling medium distribution apparatus can condense a vaporized cooling medium into a liquid cooling medium without negative pressure. This helps reduce a size of a condenser, and can reduce processing difficulty of the condenser.

According to a first aspect, an embodiment of this application provides a cooling medium distribution apparatus, including at least a first heat exchanger, a second heat exchanger, a liquid storage tank, and a delivery pump. The first heat exchanger is configured to condense a gaseous first cooling medium into a liquid first cooling medium, and the first heat exchanger has a first runner and a second runner that are isolated from each other. An input end of the first runner is configured to allow the gaseous first cooling medium to flow in, and an output end of the first runner is in communication with an input end of the liquid storage tank. An output end of the liquid storage tank is configured to be in communication with an input end of the delivery pump, and an output end of the delivery pump is configured to allow the liquid first cooling medium to flow out. The second runner is used for flowing of a second cooling medium to exchange heat with the first cooling medium in the first runner. The second heat exchanger has a third runner used for flowing of the second cooling medium, and the second heat exchanger is used to enable the second cooling medium in the third runner to exchange heat with the first cooling medium in the liquid storage tank, to reduce temperature of the first cooling medium in the liquid storage tank.

The cooling medium distribution apparatus provided in this embodiment of this application may be configured to perform two-phase heat dissipation on an electronic device. The input end of the first runner may be in communication with a first opening of the electronic device by using a first pipe, and the input end of the delivery pump may be in communication with a second opening of the electronic device by using a second pipe. When the electronic device works, the gaseous first cooling medium in the electronic device enters the first runner through the first pipe and exchanges heat with the second cooling medium in the second runner, so that the gaseous first cooling medium changes into the liquid first cooling medium and enters the liquid storage tank; and the first cooling medium in the liquid storage tank enters the fourth runner and exchanges heat with the second cooling medium in the third runner to obtain a first cooling medium whose boiling point is lower than the boiling point at normal pressure, and the delivery pump delivers the first cooling medium whose boiling point is lower than the boiling point at the normal pressure to the electronic device through the second pipe, to perform two-phase heat dissipation on the electronic device. It can be learned that the first heat exchanger is equivalent to a condenser. In addition, the first heat exchanger can condense the gaseous first cooling medium into the liquid first cooling medium without a need to work in a negative pressure state, and negative pressure design does not need to be performed on the first heat exchanger. Therefore, regardless of a size of the first heat exchanger, requirements such as a sealing requirement and structural strength of the first heat exchanger can be reduced, and this helps reduce processing difficulty of the first heat exchanger, and in addition, can further reduce production costs of the first heat exchanger. Because the second heat exchanger only needs to reduce the temperature of the first cooling medium, a small-sized second heat exchanger can meet this requirement. It is easy to form a sealed structure and improve structural strength by using the small-sized second heat exchanger, and therefore, processing difficulty of the second heat exchanger can be reduced, and production costs of the second heat exchanger can be reduced.

In one embodiment, the second heat exchanger further has a fourth runner used for flowing of the first cooling medium, and the fourth runner and the third runner are isolated from each other. An input end of the fourth runner is in communication with the output end of the liquid storage tank, and an output end of the fourth runner is in communication with the input end of the delivery pump. In this setting, temperature of the liquid first cooling medium flowing into the delivery pump can be reduced, to obtain the first cooling medium whose boiling point is lower than the boiling point at the normal pressure.

In one embodiment, the second heat exchanger includes a second housing and a second heat exchanger core. The second housing has a second cavity, a second inlet and a second outlet are disposed on an inner wall of the second cavity, both the second inlet and the second outlet are in communication with the second cavity, the second inlet is used as the input end of the fourth runner, and the second outlet is used as the output end of the fourth runner. The second heat exchanger core has the third runner, the second heat exchanger core is located in the second cavity, and an outer wall of the second heat exchanger core and the inner wall of the second cavity jointly define the fourth runner. The second heat exchanger in this structure can implement heat exchange between the first cooling medium and the second cooling medium.

In one embodiment, the second heat exchanger core is a heat exchanger.

In one embodiment, the second heat exchanger core is a tube-fin heat exchanger or a plate-fin heat exchanger, and this helps improve efficiency of heat exchange between the first cooling medium and the second cooling medium.

In one embodiment, the second heat exchanger core includes a second input tube, a second output tube, and a plurality of second helical tubes. The second input tube, the second output tube, and the plurality of second helical tubes are in communication to jointly define the third runner. In other words, internal space of the second input tube, internal space of the second output tube, and internal space of the plurality of second helical tubes are in communication to form the third runner. A first end of each second helical tube is in communication with the second input tube, and a second end of each second helical tube is in communication with the second output tube. The second input tube, the second output tube, and all the second helical tubes jointly define the third runner. The second input tube is configured to allow the second cooling medium to flow into each second helical tube. The second output tube is configured to allow the second cooling medium in the second helical tube to flow out. In this setting, heat exchange between the first cooling medium and the second cooling medium can be implemented, and a heat exchange area between the first cooling medium and the second cooling medium can be increased.

In one embodiment, the first heat exchanger, the liquid storage tank, the second heat exchanger, and the delivery pump are successively arranged from top to bottom in a gravity direction. In this setting, the first cooling medium can flow from top to bottom under the action of gravity, and this helps save energy and ensure circular flowing of the first cooling medium.

In one embodiment, the output end of the liquid storage tank is in communication with the input end of the delivery pump. The second heat exchanger is disposed in the liquid storage tank and enters the first cooling medium in the liquid storage tank. In this setting, the temperature of the first cooling medium that enters the delivery pump can also be reduced, and mounting space required by the cooling medium distribution apparatus can be reduced.

In one embodiment, the first heat exchanger, the liquid storage tank, and the delivery pump are successively arranged from top to bottom in a gravity direction. In this way, the first cooling medium may flow from top to bottom under the action of gravity, and this helps save energy and ensure circular flowing of the first cooling medium.

In one embodiment, the second heat exchanger is a tube-fin heat exchanger or a plate-fin heat exchanger, so that a heat exchange area between the first cooling medium and the second cooling medium can be increased.

In one embodiment, the second heat exchanger includes a second input tube, a second output tube, and a plurality of second helical tubes. A first end of each second helical tube is in communication with the second input tube, and a second end of each second helical tube is in communication with the second output tube. The second input tube, the second output tube, and all the second helical tubes jointly define the third runner. The second input tube is configured to allow the second cooling medium to flow into each second helical tube. The second output tube is configured to allow the second cooling medium in the second helical tube to flow out. In this setting, heat exchange between the first cooling medium and the second cooling medium can be implemented, and a heat exchange area between the first cooling medium and the second cooling medium can be increased.

In one embodiment, the first heat exchanger includes a first housing and a first heat exchanger core. The first housing has a first cavity, a first inlet and a first outlet are disposed on an inner wall of the first cavity, both the first inlet and the first outlet are in communication with the first cavity, the first inlet is used as the input end of the first runner, and the first outlet is used as the output end of the first runner. The first heat exchanger core is disposed in the first cavity and defines the first runner together with the inner wall of the first cavity, and the first heat exchanger core has the second runner. In this setting, heat exchange between the first cooling medium and the second cooling medium can be implemented.

In one embodiment, the first heat exchanger core is a heat exchanger.

In one embodiment, the first heat exchanger core is a tube-fin heat exchanger or a plate-fin heat exchanger, so that a heat exchange area between the first cooling medium and the second cooling medium can be increased.

In one embodiment, the first heat exchanger core includes a first input tube, a first output tube, and a plurality of first helical tubes. A first end of each first helical tube is in communication with the first input tube, and a second end of each first helical tube is in communication with the first output tube. The first input tube, the first output tube, and all the first helical tubes jointly define the second runner. The first input tube is configured to allow the second cooling medium to flow into each first helical tube. The first output tube is configured to allow the second cooling medium in each first helical tube to flow out. In this setting, heat exchange between the first cooling medium and the second cooling medium can be implemented, and a heat exchange area between the first cooling medium and the second cooling medium can be increased.

In one embodiment, the cooling medium distribution apparatus further includes a supply apparatus. An input end of the supply apparatus is configured to be in communication with an output end of the second runner or an output end of the third runner, and an output end of the supply apparatus is configured to be in communication with an input end of the second runner or an input end of the third runner. Through the supply apparatus, the second cooling medium can be used cyclically, and a low-temperature second cooling medium can be delivered to the second runner and the third runner.

According to a second aspect, an embodiment of this application provides a heat dissipation cabinet, including a cabinet and the cooling medium distribution apparatus according to any implementation of the first aspect. The cooling medium distribution apparatus is mounted on the cabinet. Through the cooling medium distribution apparatus in the first aspect, a gaseous first cooling medium can be condensed into a liquid first cooling medium at normal pressure, and a first cooling medium whose boiling point is lower than a boiling point at the normal pressure can be provided.

According to a third aspect, an embodiment of this application provides a server system, including an electronic device, a first pipe, a second pipe, and the cooling medium distribution apparatus according to the first aspect. Alternatively, the server system includes an electronic device, a first pipe, a second pipe, and the heat dissipation cabinet according to the second aspect, and the heat dissipation cabinet includes a cooling medium distribution apparatus. An input end of a first runner of the cooling medium distribution apparatus is in communication with a first opening of the electronic device by using the first pipe, and an output end of a delivery pump of the cooling medium distribution apparatus is in communication with a second opening of the electronic device by using the second pipe.

The cooling medium distribution apparatus provided in this embodiment of this application can condense a gaseous first cooling medium generated by the electronic device into a liquid first cooling medium, and the cooling medium distribution apparatus can work at normal pressure. In addition, the cooling medium distribution apparatus can further reduce temperature of the liquid first cooling medium obtained through condensing, to supply the electronic device with the liquid first cooling medium whose boiling point is lower than a boiling point at the normal pressure, so that two-phase heat dissipation or single-phase heat dissipation can be performed on the electronic device.

According to a fourth aspect, an embodiment of this application provides a data center, including an equipment room and at least one server system according to the second aspect that is disposed in the equipment room.

With reference to the accompanying drawings, these and other aspects, implementations, and advantages of example embodiments are to become apparent from the embodiments described below. However, it should be understood that the specification and the accompanying drawings are for illustration only and are not intended to define limitations on embodiments of this application. For details, refer to the appended claims. Other aspects and advantages of embodiments of this application are set forth in the following descriptions, and are partly apparent from the descriptions, or are learned through practice of embodiments of this application. In addition, aspects and advantages of embodiments of this application may be implemented and obtained by using means and combinations specifically noted in the appended claims.

### BRIEF DESCRIPTION OF DRAWINGS

FIG. 1 is a schematic diagram of a three-dimensional structure of a data center according to an embodiment of this application;

FIG. 2 is a schematic diagram of an internal structure of a data center according to an embodiment of this application;

FIG. 3 is a schematic diagram of a structure of a server system according to an embodiment of this application;

FIG. 4 is a schematic diagram of a structure of a cooling medium distribution apparatus according to an embodiment of this application;

FIG. 5 is a schematic sectional view of a first heat exchanger according to an embodiment of this application;

FIG. 6 is a schematic diagram of a structure of a first heat exchanger core according to an embodiment of this application;

FIG. 7 is a schematic sectional view of a second heat exchanger according to an embodiment of this application;

FIG. 8 is a schematic diagram of a structure of a second heat exchanger core according to an embodiment of this application;

FIG. 9 is a schematic diagram of a structure of another cooling medium distribution apparatus according to an embodiment of this application;

FIG. 10 is a schematic diagram of a structure in which a second heat exchanger is located in a liquid storage tank according to an embodiment of this application;

FIG. 11 is a schematic diagram of a structure of still another cooling medium distribution apparatus according to an embodiment of this application;

FIG. 12 is a schematic diagram of a structure of yet another cooling medium distribution apparatus according to an embodiment of this application; and

FIG. 13 is a schematic diagram of a structure of still yet another cooling medium distribution apparatus according to an embodiment of this application.

### DESCRIPTION OF REFERENCE NUMERALS

100: Server system;
110: Electronic device;
111: Housing; 112: To-be-cooled component; 113: Cavity; 114: First opening; 115: Second opening; 116: Cooling medium; 117: Sprayer;
120: Cooling medium distribution apparatus;
121: First heat exchanger; 1211: First runner; 1212: Second runner;
1213: First housing;
1214: First heat exchanger core; 12141: First helical tube; 12142: First input tube; 12143: First output tube;
1215: First cavity; 1216: First inlet; 1217: First outlet;
122: Liquid storage tank;
123: Second heat exchanger; 1231: Third runner; 1232: Fourth runner;
1233: Second housing;
1234: Second heat exchanger core; 12341: Second helical tube; 12342: Second input tube; 12343: Second output tube;
1235: Second cavity; 1236: Second inlet; 1237: Second outlet;
124: Deliver pump;
125: Second cooling medium;
126: Supply apparatus;
130: First pipe; 140: Second pipe;
200: Equipment room;
300: Equipment cabinet;
1000: Data center;
X: Gravity direction.

### DESCRIPTION OF EMBODIMENTS

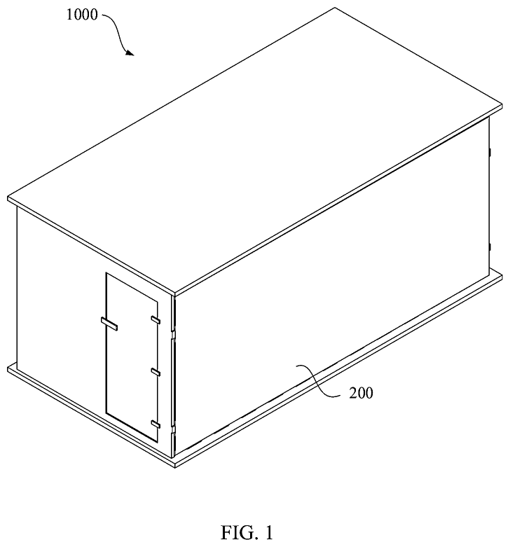

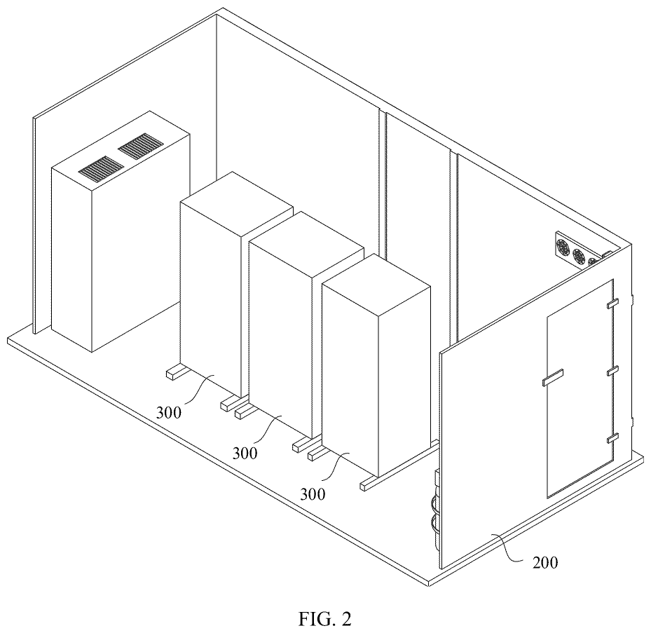

A data center 1000 is a globally coordinated network of specific devices, and is configured to convey, accelerate, display, compute, and store data information on an Internet infrastructure. An embodiment of this application provides a data center 1000. As shown in FIG. 1, the data center 1000 may include an equipment room 200. As shown in FIG. 2, at least one equipment cabinet 300 is disposed in the equipment room 200, and a quantity of equipment cabinets 300 may include but is not limited to 3 shown in the figure, for example, 50 to 100 equipment cabinets 300 may be included. A cooling system is disposed in the equipment room 200, and the cooling system provides a good operating environment for the equipment cabinet 300. In this embodiment of this application, a specific structure and a working principle of the cooling system in the equipment room 200 are not described in detail.

A plurality of equipment cabinets 300 may include one or more of a communication cabinet, a power cabinet, a server, or a heat dissipation cabinet that dissipates heat for the server. The server may be a cabinet server, a rack server, or the like. For example, the plurality of equipment cabinets 300 include at least a server and a heat dissipation cabinet. One server may correspond to one heat dissipation cabinet, or one server corresponds to a plurality of heat dissipation cabinets, or a plurality of servers correspond to one heat dissipation cabinet. It should be noted that the heat dissipation cabinet may include a frame and a heat dissipation apparatus. The frame is configured to accommodate the heat dissipation apparatus, and the heat dissipation apparatus is configured to dissipate heat for the server. The frame may be the cabinet of the server. Therefore, the heat dissipation apparatus may be integrated into the server.

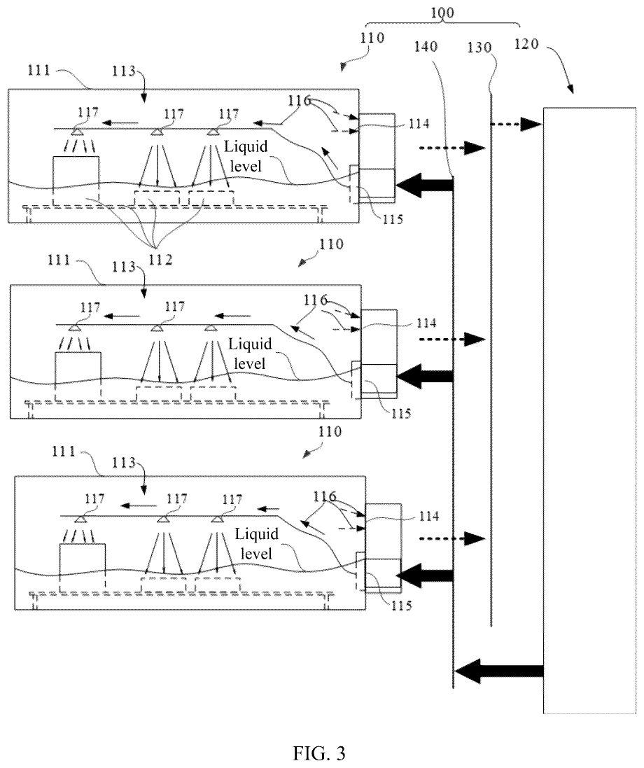

In this embodiment of this application, that one server corresponds to one heat dissipation cabinet is used as an example to describe a connection relationship between the server and the heat dissipation cabinet, and the heat dissipation cabinet and the server constitute a server system 100. FIG. 3 is a schematic diagram of a partial structure of the server system according to an embodiment of this application. As shown in FIG. 3, the server system may include a server and a heat dissipation cabin et. The server includes at least one electronic device, and a heat dissipation apparatus of the heat dissipation cabinet is a cooling medium distribution apparatus 120. When there is one electronic device, the cooling medium distribution apparatus 120 delivers a liquid first cooling medium 116 to one electronic device 110, to dissipate heat for the electronic device 110. When there are a plurality of electronic devices 110, the cooling medium distribution apparatus 120 may deliver the liquid first cooling medium 116 to all the electronic devices 110, to dissipate heat for all the electronic devices 110.

It should be noted that the liquid first cooling medium 116 delivered by the cooling medium distribution apparatus 120 may be used for two-phase heat dissipation on some electronic devices 110 and/or be used for single-phase liquid cooling heat dissipation on some electronic devices 110. For example, the cooling medium distribution apparatus 120 may supply the liquid first cooling medium 116 to the electronic device 110 in the server system 100, to perform two-phase heat dissipation on the electronic device 110. Alternatively, the cooling medium distribution apparatus 120 may perform single-phase liquid cooling heat dissipation on the electronic device 110 such as a power supply module or a switching node module in the server system 100 by using a cold plate.

The electronic device 110 may be any device that uses a two-phase heat dissipation manner, such as a computing device, a storage device, a power supply device, a switching device, or a communication device. This is not specifically limited herein. In this embodiment of this application, the cooling medium distribution apparatus 120 is described by using an example in which the liquid first cooling medium 116 is delivered to the electronic device 110.

Certainly, in another embodiment, if the server system includes a plurality of servers and a plurality of heat dissipation cabinets, one heat dissipation cabinet may provide the first cooling medium 116 for a plurality of electronic devices of the plurality of servers, to dissipate heat for all the electronic devices 110.

As shown in FIG. 3, the electronic device 110 includes a housing 111 and a to-be-cooled component 112 immersed in the first cooling medium 116. A cavity 113 for accommodating the first cooling medium 116 is formed in the housing 111, and a first opening 114 and a second opening 115 that are in communication with the cavity 113 are disposed on a sidewall of the housing 111. The first opening 114 may be in communication with an input end of the cooling medium distribution apparatus 120 by using a first pipe 130. The second opening 115 may be in communication with an output end of the cooling medium distribution apparatus 120 by using a second pipe 140. In this setting, a vaporized first cooling medium 116 generated in the housing 111 may be discharged into the cooling medium distribution apparatus 120 through the first opening 114. In addition, the cooling medium distribution apparatus 120 may deliver the liquid first cooling medium 116 to the cavity 113 through the second opening 115, to perform two-phase heat dissipation on the to-be-cooled component 112 in the electronic device 110.

Two-phase heat dissipation means that the liquid first cooling medium 116 changes from a liquid state to a gaseous state after absorbing heat generated by the to-be-cooled component 112. A large amount of heat may be absorbed in a phase change process of the first cooling medium 116, so that temperature of the to-be-cooled component 112 can be reduced.

That the to-be-cooled dissipation component 112 is immersed in the first cooling medium 116 may be understood as follows: In a height direction of the electronic device 110, a part of the to-be-cooled dissipation component 112 is immersed in the first cooling medium 116, and the other part of the to-be-cooled dissipation component 112 is located above a liquid level of the first cooling medium 116; or the entire to-be-cooled dissipation component 112 is immersed in the first cooling medium 116.

It should be noted that the to-be-cooled component 112 is a general term of all heat emitting components, and the heat emitting component may be a component such as a circuit board, a resistor, a central processing unit, a graphics processing unit, a heat sink, a capacitor, a power supply, or a memory. In addition, there may be one or more heat emitting components of each type, and this is not specifically limited herein.

In this embodiment of this application, as shown in FIG. 3, each electronic device 110 further includes at least one sprayer 117, all sprayers 117 are disposed in the cavity 113, and the sprayer 117 may be configured to spray the liquid first cooling medium 116 toward the to-be-cooled component 112, to increase a heat dissipation capability of an electronic device. The sprayer 117 may be in communication with an output end of the cooling medium distribution apparatus 120 by using the first opening 114, so that the cooling medium distribution apparatus 120 can deliver the liquid first cooling medium 116 to the sprayer 117.

The sprayer 117 may spray the liquid first cooling medium 116 toward the to-be-cooled component 112 below the liquid level of the first cooling medium 116, or the sprayer 117 may spray the liquid first cooling medium 116 toward the to-be-cooled component 112 above the liquid level of the first cooling medium 116; or there are a plurality of sprayers 117, and the sprayers 117 may simultaneously spray the liquid first cooling medium 116 toward the to-be-cooled component 112 below the liquid level and the to-be-cooled component 112 above the liquid level.

When the liquid first cooling medium 116 sprayed by the sprayer 117 is directly hit on a surface of the to-be-heat dissipation component 112, a single-point heat dissipation capability of the to-be-heat dissipation component 112 can be increased, and in addition, a speed at which the gaseous first cooling medium 116 leaves the liquid first cooling medium 116 can be further increased. The single-point heat dissipation capability is a heat dissipation capability of an area that is on the to-be-cooled component 112 and that cooperates with the sprayer 117. Specifically, the area refers to heat emitting components at different locations on the to-be-cooled component 112.

The sprayer 117 may continuously spray the liquid first cooling medium 116 toward the to-be-cooled component 112, or the sprayer 117 may spray the liquid first cooling medium 116 toward the to-be-cooled component 112 at preset time intervals. Therefore, a jet flow of the first cooling medium 116 impacts a surface of the to-be-cooled component 112. In one aspect, a gaseous first cooling medium 116 formed near a collision point can be rapidly separated from the liquid first cooling medium 116, so that the gaseous first cooling medium 116 enters the cooling medium distribution apparatus 120 through the first opening 114, to avoid a case in which a phase change rate of the liquid first cooling medium 116 is reduced due to relatively high ambient temperature near the collision point. In another aspect, the jet flow of the first cooling medium 116 can increase a speed of replenishing the liquid first cooling medium 116 near the collision point, to increase a speed of replacing the liquid first cooling medium 116, and therefore, the single-point heat dissipation capability of the to-be-cooled component 112 can be increased.

In this embodiment of this application, one of functions of the cooling medium distribution apparatus 120 is to condense the gaseous first cooling medium 116 into the liquid first cooling medium 116, and another function is to deliver again the liquid first cooling medium 116 obtained through condensing into the cavity 113 of the electronic device 110, to dissipate heat for the to-be-cooled component 112.

In a related technology, a cooling medium distribution apparatus includes a condenser, a liquid storage tank, and a delivery pump. An input end of the condenser is in communication with the first opening of the electronic device by using the first pipe, an output end of the condenser is in communication with an input end of the liquid storage tank, and an output end of the liquid storage tank is in communication with an input end of the delivery pump. An output end of the delivery pump is in communication with the second opening of the electronic device by using the second pipe. The delivery pump may deliver a liquid first cooling medium in the liquid storage tank to the cavity. In a process of condensing a gaseous first cooling medium into a liquid first cooling medium, internal pressure of the condenser is in a negative pressure state, to ensure that the first cooling medium is cooled to its boiling point which is lower than the boiling point at normal pressure. However, to maintain the negative pressure state, during negative pressure design of the condenser, targeted designs are required, for example, measures such as increasing structural strength of the condenser and improving sealing performance of a sealing structure are taken, to ensure that in a condensing process, the sealing structure of the condenser is not deformed, and no crack occurs on the condenser. However, a larger size of the condenser correspondingly leads to higher processing difficulty in negative pressure design. Negative pressure is a gas pressure state that is lower than normal pressure (that is, one barometric pressure).

To resolve the foregoing problem, an embodiment of this application provides a cooling medium distribution apparatus 120. The cooling medium distribution apparatus 120 includes two heat exchangers. One heat exchanger may condense a gaseous first cooling medium 116 at normal pressure into a liquid first cooling medium 116, and the other heat exchanger may reduce current temperature of the liquid first cooling medium 116 to predetermined temperature, so that the liquid first cooling medium 116 whose boiling point is lower than a boiling point at the normal pressure can be provided, to perform two-phase heat dissipation on an electronic device 110. A condensing process and a cooling process of the first cooling medium 116 each correspond to one heat exchanger, and therefore, negative pressure design is limited to a heat exchanger used in the cooling process. However, a volume of the heat exchanger used in the cooling process is small, so that difficulty of the negative pressure design can be reduced, and processing difficulty of the heat exchanger used in the cooling process can be reduced. In addition, a heat exchanger used for condensing can work at the normal pressure. Therefore, regardless of a size of the heat exchanger used for condensing, processing difficulty of the heat exchanger for condensing can be reduced.

The predetermined temperature is a preset temperature value of the first cooling medium 116, for example, a temperature value such as 2° C., 10° C., or 20° C.°. It may be understood that the predetermined temperature is lower than the current temperature of the first cooling medium 116.

The cooling medium distribution apparatus 120 provided in this embodiment of this application is described in detail below by using specific implementations.

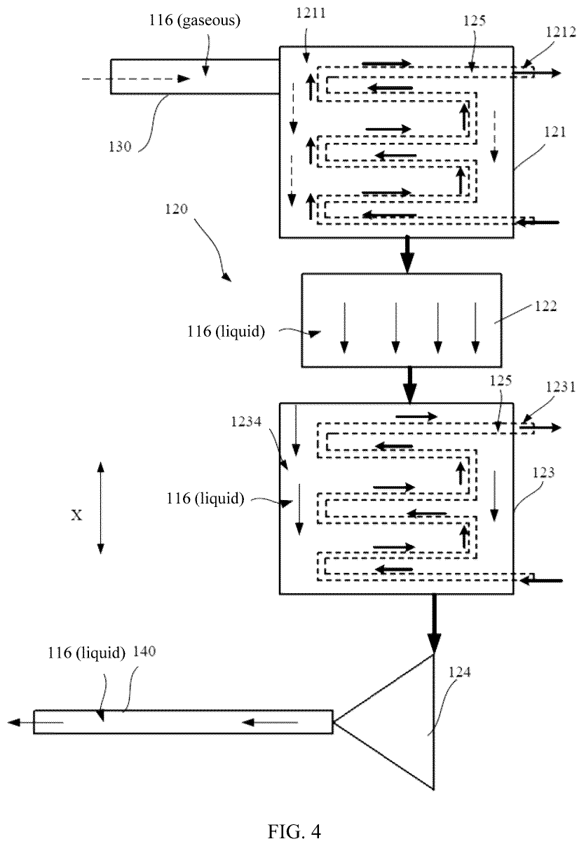

FIG. 4 is a schematic diagram of a structure of a cooling medium distribution apparatus according to an embodiment of this application.

An embodiment of this application provides a cooling medium distribution apparatus 120. As shown in FIG. 4, the cooling medium distribution apparatus 120 includes at least a first heat exchanger 121, a liquid storage tank 122, a second heat exchanger 123, and a delivery pump 124. The first heat exchanger 121 includes a first runner 1211 and a second runner 1212 that are isolated from each other. An input end of the first runner 1211 is configured to be in communication with a first opening 114 of an electronic device 110, and an output end of the first runner 1211 is in communication with an input end of the liquid storage tank 122. An output end of the liquid storage tank 122 is in communication with an input end of the delivery pump 124 by using the second heat exchanger 123, and an output end of the delivery pump 124 is configured to be in communication with a second opening 115 of the electronic device 110.

Still as shown in FIG. 4, the first heat exchanger 121 may include a first housing and a first bent tube. An inner side of the first bent tube is not in communication with an inner side of the first housing. An outer wall of the first bent tube and an inner wall of the first housing jointly define the first runner 1211, and an inner wall of the first bent tube defines the second runner 1212. Therefore, a first cooling medium 116 that enters the first runner 1211 from the electronic device 110 may exchange heat with a second cooling medium 125 in the second runner 1212 without coming into contact with the second cooling medium 125. A shape of the first runner 1211 may be a regular or irregular shape such as a spiral shape or a wave shape. This is not specifically limited herein. A shape of the second runner 1212 may be a regular or irregular shape such as a spiral shape or a wave shape. This is not specifically limited herein. When the shape of the second runner 1212 is a spiral shape or a wave shape, it helps increase a contact area between the first runner 1211 and the second runner 1212, and can improve efficiency of heat exchange between the first cooling medium 116 and the second cooling medium 125.

Still as shown in FIG. 4, the second heat exchanger 123 has a third runner 1231 and a fourth runner 1232 that are isolated from each other. An input end of the fourth runner 1232 is in communication with the output end of the liquid storage tank 122, and the output end of the fourth runner 1232 is in communication with the input end of the delivery pump 124. Therefore, the first cooling medium 116 in the liquid storage tank 122 can enter the delivery pump 124 through the fourth runner 1232. The third runner 1231 is used for flowing of the second cooling medium 125 to exchange heat with the first cooling medium 116 in the fourth runner 1232.

Still as shown in FIG. 4, the second heat exchanger 123 may include a second housing and a second bent tube. An inner side of the second bent tube is not in communication with an inner side of the second housing. An outer wall of the second bent tube and an inner wall of the second housing jointly define the fourth runner 1232, and an inner wall of the second bent tube defines the third runner 1231. Therefore, the first cooling medium 116 in the fourth runner 1232 can exchange heat with the second cooling medium 125 in the third runner 1231 to reduce temperature of the first cooling medium 116.

A shape of the third runner 1231 may be a regular or irregular shape such as a spiral shape or a wave shape. This is not specifically limited herein. A shape of the fourth runner 1232 may be a regular or irregular shape such as a spiral shape or a wave shape. This is not specifically limited herein. When both the third runner 1231 and the fourth runner 1232 are spiral shapes or wave shapes, efficiency of heat exchange between the first cooling medium 116 and the second cooling medium 125 is improved.

Still as shown in FIG. 4, in a gravity direction (for example, in an X direction in FIG. 4), the first heat exchanger 121, the liquid storage tank 122, the second heat exchanger 123, and the delivery pump 124 are successively arranged from top to bottom. The first cooling medium 116 can flow from top to bottom under the action of gravity, and this helps save energy and ensure circular flowing of the first cooling medium 116. Certainly, in another embodiment, the first heat exchanger 121, the liquid storage tank 122, the second heat exchanger 123, and the delivery pump 124 may alternatively not be successively arranged from top to bottom.

Still as shown in FIG. 3 and FIG. 4, when the electronic device 110 works, the gaseous first cooling medium 116 in the electronic device 110 enters the first runner 1211 through the first pipe 130 and exchanges heat with the second cooling medium 125 in the second runner 1212, so that the gaseous first cooling medium 116 changes into the liquid first cooling medium 116 and enters the liquid storage tank 122; and the first cooling medium 116 in the liquid storage tank 122 enters the fourth runner 1232 and exchanges heat with the second cooling medium 125 in the third runner 1231, to obtain a first cooling medium 116 whose boiling point is lower than a boiling point at the normal pressure, and the delivery pump 124 delivers the first cooling medium 116 whose boiling point is lower than the boiling point at the normal pressure to the electronic device 110 through the second pipe 140, to perform two-phase heat dissipation on the electronic device 110.

In this embodiment of this application, a function of the first heat exchanger 121 in this embodiment of this application is to condense the gaseous first cooling medium 116 into the liquid first cooling medium 116; in other words, the first heat exchanger 121 is equivalent to a condenser. In addition, the first heat exchanger 121 can condense the gaseous first cooling medium 116 into the liquid first cooling medium 116 without a need to work in a negative pressure state, and negative pressure design may not be performed on the first heat exchanger 121. Therefore, regardless of a size of the first heat exchanger 121, requirements such as a sealing requirement and structural strength of the first heat exchanger 121 can be reduced, and this helps reduce processing difficulty of the first heat exchanger 121, and in addition, can further reduce production costs of the first heat exchanger 121.

In this embodiment of this application, a function of the second heat exchanger 123 in this embodiment of this application is to reduce temperature of the liquid first cooling medium 116, to obtain the liquid first cooling medium 116 whose boiling point is lower than the boiling point at the normal pressure. Therefore, negative pressure design needs to be performed on the second heat exchanger 123. However, because the second heat exchanger 123 only needs to reduce the temperature of the first cooling medium 116, a small-sized second heat exchanger 123 can meet this requirement. It is easy to form a sealed structure and improve structural strength by using the small-sized second heat exchanger 123. Therefore, processing difficulty of the second heat exchanger 123 can be reduced, and production costs of the second heat exchanger 123 can be reduced.

In this embodiment of this application, the first cooling medium 116 may be non-conductive liquid with a low boiling point. For example, the first cooling medium 116 is fluorinated liquid. In addition, a boiling point of the first cooling medium 116 at the normal pressure may be 30° C. to 60° C. Certainly, a specific type of the first cooling medium 116 is not specifically limited herein.

In this embodiment of this application, the second cooling medium 125 may be a cooling medium such as a refrigerant or water. In addition, the second cooling medium 125 may also be non-conductive liquid with a low boiling point. For example, the second cooling medium 125 is fluorinated liquid, or the second cooling medium 125 may be alternatively cooling water. A specific type of the second cooling medium 125 is not limited herein. In addition, it should be noted that a specific type of the second cooling medium 125 in the first heat exchanger 121 may be the same as or different from a specific type of the second cooling medium 125 in the second heat exchanger 123, and this is not specifically limited herein. For example, the second cooling medium 125 in the first heat exchanger 121 and the second cooling medium 125 in the second heat exchanger 123 are both cooling water.

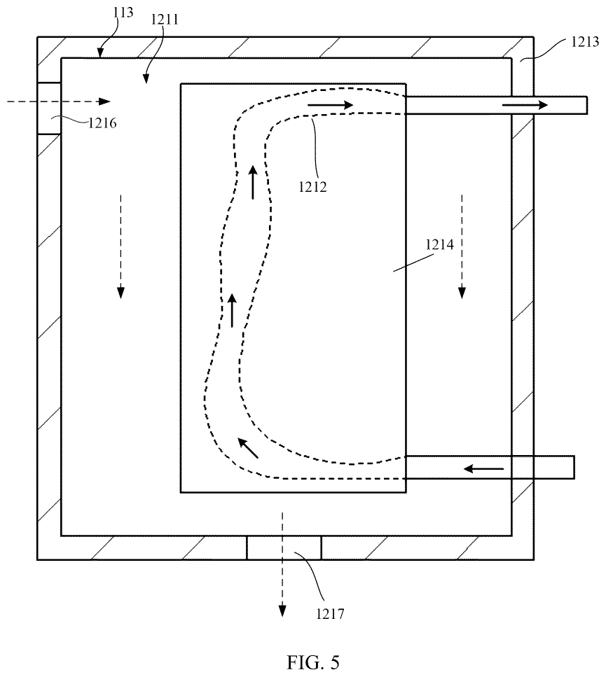

FIG. 5 is a schematic sectional view of the first heat exchanger according to an embodiment of this application.

In some possible implementations, as shown in FIG. 5, the first heat exchanger 121 may include a first housing 1213 and a first heat exchanger core 1214. There is a first cavity 1215 inside the first housing 1213, and the first heat exchanger core 1214 is disposed in the first cavity 113 and defines the first runner 1211 together with an inner wall of the first cavity 1215. A first inlet 1216 and a first outlet 1217 are disposed on the inner wall of the first cavity 1215, and both the first inlet 1216 and the first outlet 1217 are in communication with the first cavity 1215. The first inlet 1216 is used as the input end of the first runner 1211, and the first outlet 1217 is used as the output end of the first runner 1211. In addition, the first heat exchanger core 1214 has the second runner 1212. In this setting, the second cooling medium 125 can exchange heat with the gaseous first cooling medium 116.

A shape of the first housing 1213 may be a cylinder, a cuboid, or the like. This is not specifically limited herein. For example, in this embodiment of this application, the shape of the first housing 1213 is a cuboid.

The first inlet 1216 may be disposed on a side wall or a top wall of the first housing 1213. This is not specifically limited herein. For example, in this embodiment of this application, the first inlet 1216 may be disposed on the sidewall of the first housing 1213.

To ensure that all liquid first cooling mediums 116 formed in the first cavity 113 can enter the liquid storage tank 122, the first outlet 1217 may be disposed on a bottom wall of the first housing 1213, and in addition, the first outlet 1217 may be disposed in an area that is on the bottom wall of the first housing 1213 and that is located at a lowest height in the gravity direction.

A function of the first heat exchanger core 1214 is to separate the second cooling medium 125 from the gaseous first cooling medium 116 and enable the second cooling medium 125 to exchange heat with the gaseous first cooling medium 116. Therefore, a structure of the first heat exchanger core 1214 is not specifically limited herein. The first cooling medium 116 may flow from bottom to top (for example, as shown in FIG. 5), or the first cooling medium 116 may flow from top to bottom (not shown in the figure). This is not specifically limited herein.

In some examples, the first heat exchanger core 1214 may be a heat exchanger. For example, the first heat exchanger core 1214 may be a tube-fin heat exchanger, a plate-fin heat exchanger, or the like. When the first heat exchanger core 1214 is a tube-fin heat exchanger or a plate-fin heat exchanger, a contact area between the second cooling medium 125 and the gaseous first cooling medium 116 can be increased, and efficiency of heat exchange between the gaseous first cooling medium 116 and the second cooling medium 125 can be improved.

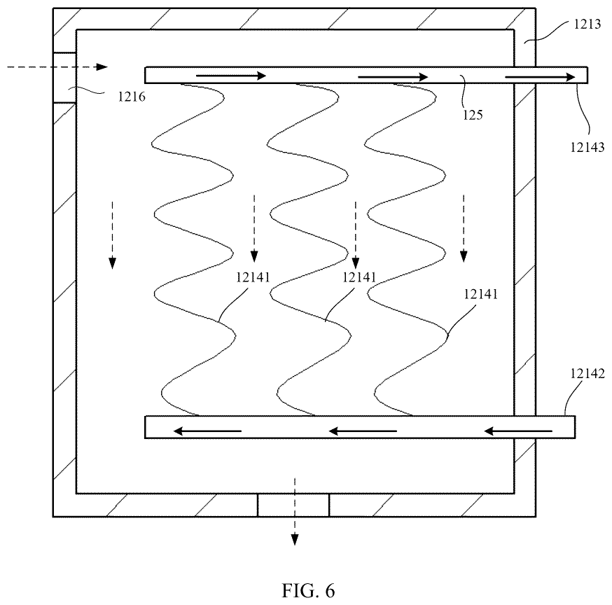

FIG. 6 is a schematic diagram of a structure of the first heat exchanger core according to an embodiment of this application.

In some examples, as shown in FIG. 6, the first heat exchanger core 1214 may also include a plurality of first helical tubes 12141, a first input tube 12142, and a first output tube 12143. First ends of the plurality of first helical tubes 12141 are in communication with the first input tube 12142, and second ends of the plurality of first helical tubes 12141 are in communication with the first output tube 12143. The first input tube 12142 is configured to enable the second cooling medium 125 to be simultaneously input into the plurality of first helical tubes 12141 and is configured to be in communication with an output end of a supply apparatus 126. The first output tube 12143 is configured to enable second cooling mediums 125 in the plurality of first helical tubes 12141 to enter the supply apparatus 126 to implement circulation of the second cooling medium 125.

It may be understood that each first helical tube 12141, a part of the first output tube 12143, and a part of the first input tube 12142 define the second runner 1212 together with the inner wall of the first cavity 1215.

Still as shown in FIG. 4, because the second heat exchanger 123 is located between the delivery pump 124 and the liquid storage tank 122, the second heat exchanger 123 has at least the third runner 1231 and the fourth runner 1232, to ensure heat exchange between the first cooling medium 116 and the second cooling medium 125. Therefore, in some possible implementations, the second heat exchanger 123 may be a plate heat exchanger, and when the plate heat exchanger is used, the second cooling medium 125 can exchange heat with the liquid first cooling medium 116, to reduce the temperature of the first cooling medium 116.

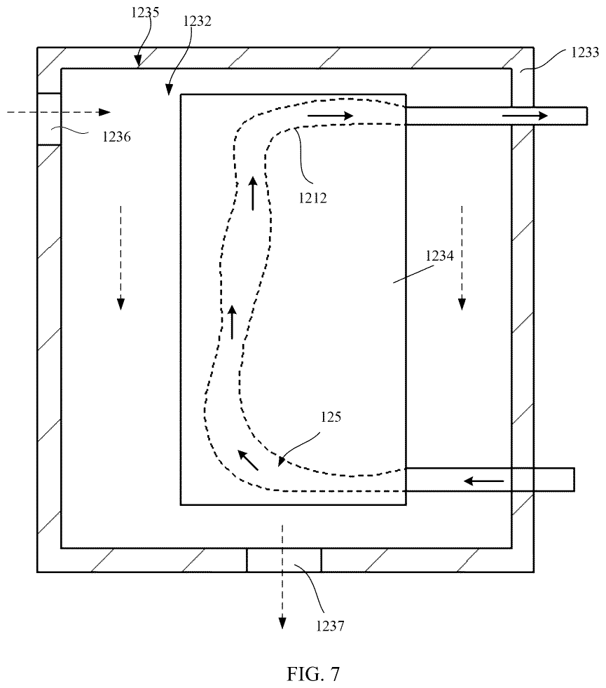

FIG. 7 is a schematic sectional view of the second heat exchanger according to an embodiment of this application.

In other possible implementations, as shown in FIG. 7, the second heat exchanger 123 may include a second housing 1233 and a second heat exchanger core 1234. The second housing 1233 has a second cavity 1235. The second heat exchanger core 1234 is located in the second cavity 1235. An outer wall of the second heat exchanger core 1234 and an inner wall of the second cavity 1235 jointly define the fourth runner 1232. A second inlet 1236 and a second outlet 1237 are disposed on the inner wall of the second cavity 1235, and both the second inlet 1236 and the second outlet 1237 are in communication with the second cavity 1235. The second inlet 1236 is used as the input end of the fourth runner 1232 and is configured to be in communication with the output end of the liquid storage tank 122, so that the liquid first cooling medium 116 can enter the second heat exchanger 123. The second outlet 1237 is used as the output end of the fourth runner 1232 and is configured to be in communication with the input end of the delivery pump 124, so that the liquid first cooling medium 116 cooled by the second heat exchanger 123 can be delivered to the cavity 113 of the electronic device 110.

The second heat exchanger core 1234 has the third runner 1231 that is separated from the fourth runner 1232, and the third runner 1231 is used for flowing of the second cooling medium 125, so that the second cooling medium 125 can exchange heat with the first cooling medium 116 in the fourth runner 1232 without coming into contact with the first cooling medium 116.

Still as shown in FIG. 7, to improve a rate at which the first cooling medium 116 enters the fourth runner 1232 from the first runner 1211 and a rate at which the first cooling medium 116 enters the delivery pump 124 from the fourth runner 1232, the second inlet 1236 may be disposed on a top wall of the second housing 1233, the second outlet 1237 may be disposed on a bottom wall of the second housing 1233, and in addition, the top wall and the bottom wall of the second housing 1233 are disposed relative to each other in the gravity direction.

It may be understood that a function of the second heat exchanger core 1234 is to separate the second cooling medium 125 from the gaseous first cooling medium 116 and enable the second cooling medium 125 to exchange heat with the gaseous first cooling medium 116. Therefore, a specific structure of the second heat exchanger core 1234 is not specifically limited herein.

In some examples, the second heat exchanger core 1234 may be a heat exchanger. For example, the second heat exchanger core 1234 may be a tube-fin heat exchanger, a plate-fin heat exchanger, or the like. It may be understood that when the second heat exchanger 1234 is a tube-fin heat exchanger or a plate-fin heat exchanger, it helps increase a contact area between the second cooling medium 125 and the liquid first cooling medium 116, and can improve efficiency of heat exchange between the liquid first cooling medium 116 and the second cooling medium 125.

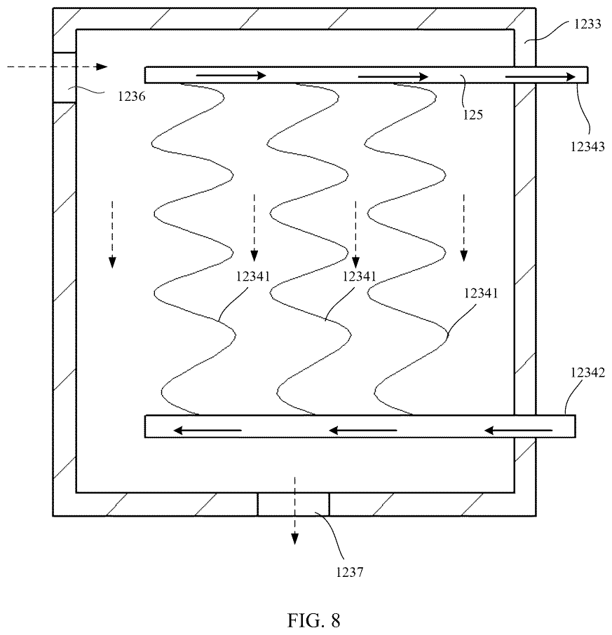

FIG. 8 is a schematic diagram of a structure of the second heat exchanger core according to an embodiment of this application.

In some examples, as shown in FIG. 8, the second heat exchanger core 1234 may also include a plurality of second helical tubes 12341, a second input tube 12342, and a second output tube 12343. First ends of the plurality of second helical tubes 12341 are in communication with the second input tube 12342, and second ends of the plurality of second helical tubes 12341 are in communication with the second output tube 12343. The second input tube 12342 is configured to enable the second cooling medium 125 to be simultaneously input into the plurality of second helical tubes 12341 and is configured to be in communication with an output end of a supply apparatus 126. The second output tube 12343 is configured to enable second cooling mediums 125 in the plurality of second helical tubes 12341 to enter the supply apparatus 126 to implement circulation of the second cooling medium 125.

It may be understood that each second helical tube 12341, a part of the second output tube 12343, and a part of the second input tube 12342 jointly define the third runner 1231.

In descriptions in the foregoing content, the second heat exchanger 123 is disposed between the liquid storage tank 122 and the delivery pump 124 to reduce the temperature of the first cooling medium 116 that enters the delivery pump 124. However, the second heat exchanger 123 may be disposed in the liquid storage tank 122 and immersed in the first cooling medium 116, to reduce the temperature of the first cooling medium 116 that enters the delivery pump 124. A structure of the cooling medium distribution apparatus 120 in which the second heat exchanger 123 is located in the liquid storage tank 122 is described in detail below.

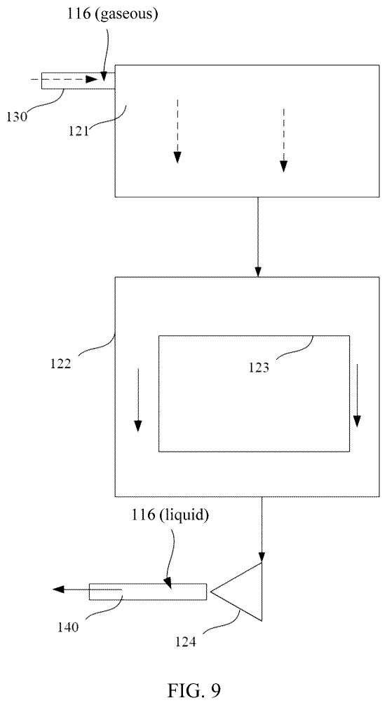

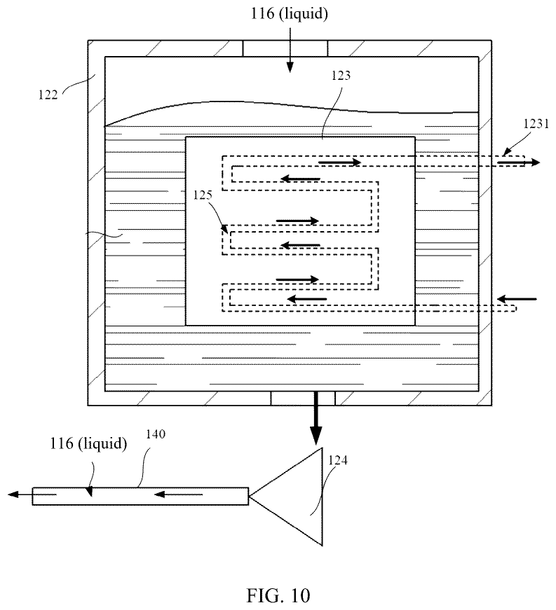

FIG. 9 is a schematic diagram of a structure of another cooling medium distribution apparatus according to an embodiment of this application. FIG. 10 is a schematic diagram of a structure in which a second heat exchanger is located in a liquid storage tank according to an embodiment of this application.

As shown in FIG. 10, another cooling medium distribution apparatus 120 provided in an embodiment of this application includes at least a first heat exchanger 121, a liquid storage tank 122, a second heat exchanger 123, and a delivery pump 124. The cooling medium distribution apparatus 120 in this embodiment is approximately the same as the cooling medium distribution apparatus 120 shown in FIG. 4. A same part is not described again. A difference lies in that an output end of the liquid storage tank 122 is in communication with an input end of the delivery pump 124, and an output end of the delivery pump 124 is in communication with a second opening 115 of an electronic device 110 by using a second pipe 140. The second heat exchanger 123 is disposed in the liquid storage tank 122 and immersed in a first cooling medium 116 in the liquid storage tank 122.

Still as shown in FIG. 4 and FIG. 10 in the foregoing content, a gaseous first cooling medium 116 generated when the electronic device 110 works enters a first runner 1211 through a first pipe 130 and exchanges heat with a second cooling medium 125 in a second runner 1212, so that the gaseous first cooling medium 116 is condensed into a liquid first cooling medium 116 and enters the liquid storage tank 122. The second heat exchanger 123 is in contact with the first cooling medium 116 and enables the first cooling medium 116 to exchange heat with the second cooling medium 125, to reduce temperature of the first cooling medium 116, so that a boiling point of the first cooling medium 116 that enters the delivery pump 124 can be lower than a boiling point at normal pressure.

Still as shown in FIG. 9, in a gravity direction (for example, in the X direction in FIG. 4), the first heat exchanger 121, the liquid storage tank 122, and the delivery pump 124 are successively arranged from top to bottom, and the first cooling medium 116 may flow from top to bottom under the action of gravity, and this helps save energy and ensure circular flowing of the first cooling medium 116. Certainly, in another embodiment, the first heat exchanger 121, the liquid storage tank 122, and the delivery pump 124 may alternatively not be successively arranged from top to bottom.

It should be noted that a structure of the first heat exchanger 121 may be a structure of the first heat exchanger 121 shown in FIG. 4 to FIG. 6 in the foregoing content. Therefore, the first heat exchanger 121 has the first runner 1211 and the second runner 1212. A connection relationship between and structures of the first runner 1211 and the second runner 1212 are described in detail in the foregoing content, and are not described in detail herein. In addition, the first cooling medium 116 and the second cooling medium 125 are also described in detail in the foregoing content, and therefore are not described in detail herein.

To enable the second cooling medium 125 to exchange heat with the first cooling medium 116 in the liquid storage tank 122 without coming into contact with the first cooling medium 116 in the liquid storage tank 122, as shown in FIG. 10, the second heat exchanger 123 has a third runner 1231 used for flowing of the second cooling medium 125, and the third runner 1231 is not in communication with internal space of the liquid storage tank 122, so that the second cooling medium 125 is not in contact with the first cooling medium 116.

Still as shown in FIG. 10, there is a gap between the second heat exchanger 123 and the output end of the liquid storage tank 122, to ensure that the first cooling medium 116 in the liquid storage tank 122 can enter the delivery pump 124.

Still as shown in FIG. 10, the second heat exchanger 123 is integrated into the liquid storage tank 122. Therefore, the second heat exchanger 123 and the liquid storage tank 122 may also be equivalent to one heat exchanger. An inner wall of the liquid storage tank 122 and an outer wall of the second heat exchanger 123 jointly form a fifth runner used for flowing of the liquid first cooling medium 116.

The second heat exchanger 123 is only used for flowing of the second cooling medium 125. Therefore, in some examples, the second heat exchanger 123 may be a heat exchanger such as a tube-fin heat exchanger or a plate-fin heat exchanger. This is not specifically limited herein. Certainly, the second heat exchanger 123 may also use the structure of the second heat exchanger core 1234 shown in FIG. 8 in the foregoing content; in other words, a heat exchanger defined by the liquid storage tank 122 and the second heat exchanger 123 is the heat exchanger shown in the foregoing content in FIG. 8.

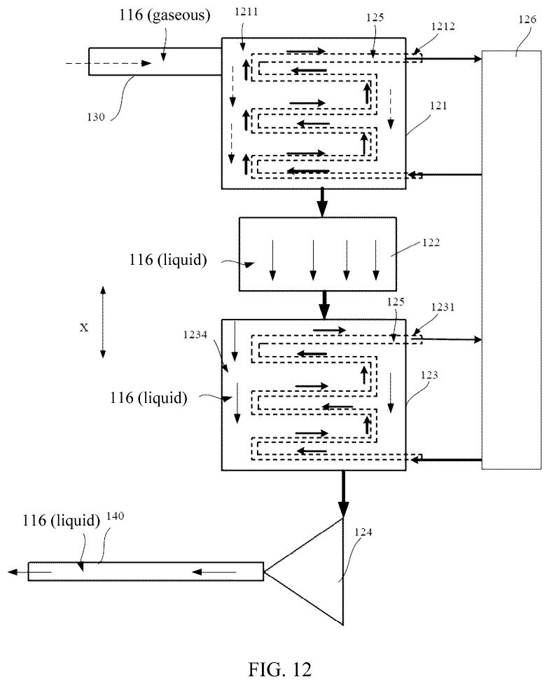

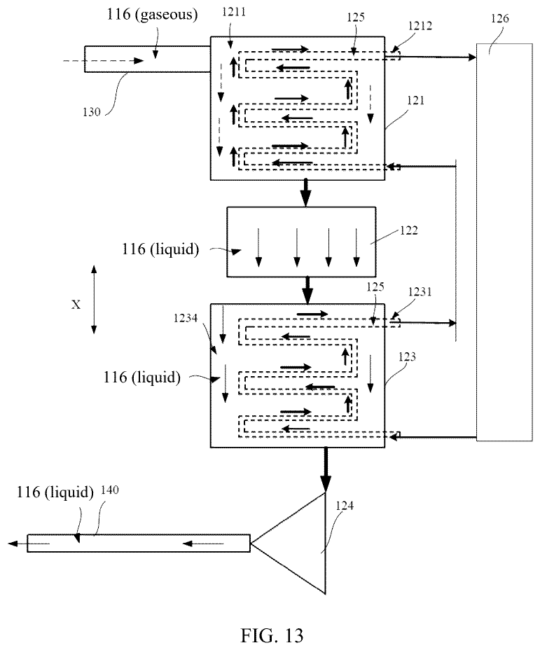

FIG. 12 is a schematic diagram of a structure of yet another cooling medium distribution apparatus according to an embodiment of this application. FIG. 13 is a schematic diagram of a structure of still yet another cooling medium distribution apparatus according to an embodiment of this application.

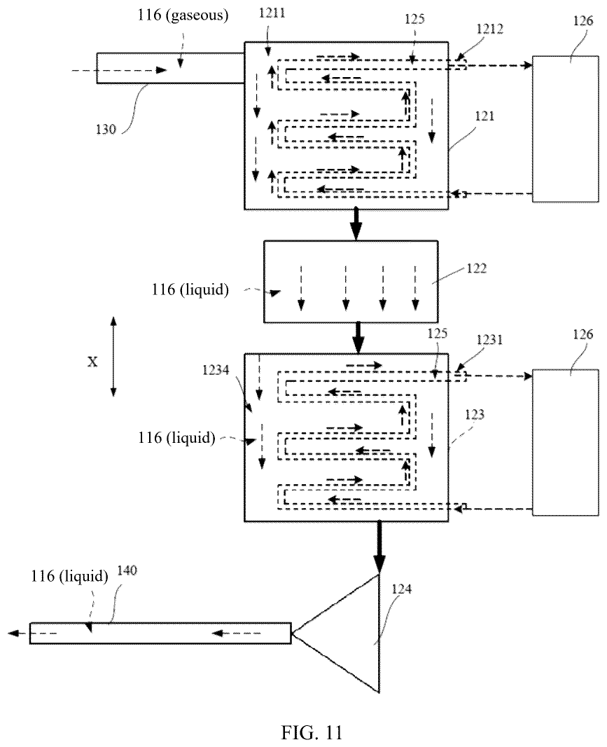

In this embodiment of this application, to deliver the second cooling medium 125 to the first heat exchanger 121 and the second heat exchanger 123, as shown in FIG. 11 to FIG. 13, the cooling medium distribution apparatus 120 further includes at least one supply apparatus 126. A quantity of supply apparatuses 126 may be determined based on a use requirement. For example, as shown in FIG. 11, the first heat exchanger 121 and the second heat exchanger 123 may each correspond one supply apparatus 126. Alternatively, as shown in FIG. 12 or FIG. 13, the first heat exchanger 121 and the second heat exchanger 123 may share a same supply apparatus 126. The supply apparatus 126 may include a supply pump (not shown in the figure) and a cooling tower (not shown in the figure).

An arrangement manner of the supply apparatus 126 shown in FIG. 11 is used as an example. The cooling tower has an input end and an output end. The input end of the cooling tower is in communication with an output end of the second runner 1212 or an output end of the third runner 1231, and the output end of the cooling tower is in communication with an input end of the supply pump. An output end of the supply pump is in communication with the input end of the second runner 1212 or the input end of the third runner 1231.

When the supply apparatus 126 works, the cooling tower may reduce temperature of a second cooling medium 125 that enters the cooling tower from the second runner 1212 and the third runner 1231 to obtain a low-temperature second cooling medium 125, so that the supply pump can deliver the low-temperature second cooling medium 125 to the first heat exchanger 121 and the second heat exchanger 123.

The second cooling medium 125 in the cooling tower may exchange heat with air in an external environment of the cooling tower, to reduce the temperature of the second cooling medium 125.

It may be understood that, in addition to reducing the temperature of the second cooling medium 125 by using the cooling tower, the supply apparatus 126 further cooperates with the supply pump by using a third heat exchanger. The third heat exchanger may be immersed in cooling water in a cooling tank, so that the second cooling medium 125 performs liquid-liquid heat exchange with the cooling water; or the third heat exchanger may be a plate heat exchanger, so that the second cooling medium 125 can exchange heat with the cooling water.

Because the first heat exchanger 121 and the second heat exchanger 123 each have a runner used for flowing of the second cooling medium 125, the second runner 1212 of the first heat exchanger 121 and the third runner 1231 of the second heat exchanger 123 may be disposed in parallel (for example, shown in FIG. 12) or in series (for example, shown in FIG. 13) relative to the supply apparatus 126. This is not specifically limited herein.

When the second runner 1212 and the third runner 1231 may be disposed in parallel, the second runner 1212 and the third runner 1231 are separately in communication with the supply apparatus 126. Specifically, an input end of the second runner 1212 and an input end of the third runner 1231 are respectively in communication with a first output end and a second output end of the supply pump, and an output end of the second runner 1212 and an output end of the third runner 1231 are respectively in communication with a first input end and a second input end of the cooling tower.

When the second runner 1212 and the third runner 1231 may be disposed in series, in some examples, an input end of the second runner 1212 is in communication with an output end of the supply pump, an output end of the second runner 1212 is in communication with an input end of the third runner 1231, and an output end of the third runner 1231 is in communication with the input end of the cooling tower. Alternatively, in another example, an input end of the third runner 1231 is in communication with an output end of the supply pump, an output end of the third runner 1231 is in communication with an input end of the second runner 1212 (for example, shown in FIG. 11), and an output end of the second runner 1212 is in communication with the input end of the cooling tower.

In the descriptions of the embodiments of this application, it should be noted that, unless otherwise specified or limited, terms “mount”, “connected”, and “connect” shall be understood in a broad sense, for example, may be a fixed connection, may be an indirect connection by using an intermediate medium, or may be communication between the inside of two elements or an interaction relationship between two elements. A person of ordinary skill in the art may understand specific meanings of the foregoing terms in the embodiments of this application based on a specific case.

In the embodiments of this application, it should be noted that an orientation or positional relationship indicated by terms “up”, “down”, “inside”, “outside”, “front”, “back”, “left”, “right”, and the like is intended only to facilitate the descriptions of this application and simplification of the descriptions rather than indicating or implying that an apparatus or an element indicated must have a specific orientation, or be constructed and operated in a specific orientation, and therefore cannot be construed as a limitation to this application. In the descriptions of the embodiments of this application, unless otherwise accurately and specifically specified, “a plurality of” means two or more.

In the specification, claims, and accompanying drawings of the embodiments of this application, terms “first”, “second”, “third”, “fourth”, and so on (if any) are intended to distinguish between similar objects but do not necessarily indicate a specific order or sequence. It should be understood that the terms used in such a way are interchangeable in proper circumstances, so that the embodiments of this application described herein can be implemented in an order other than the order illustrated or described herein. Moreover, terms “include”, “have”, and any other variants thereof are intended to cover non-exclusive inclusion, for example, a process, method, system, product, or device that includes a series of operations or units is not necessarily limited to those operations or units that are clearly listed, but may include other operations or units that are not clearly listed or that are inherent to such a process, method, system, product, or device.

Finally, it should be noted that the foregoing embodiments are merely intended for describing the technical solutions of the embodiments of this application, instead of limiting the embodiments of this application. Although this application is described in detail with reference to the foregoing embodiments, a person of ordinary skill in the art should understand that modifications may still be made to the technical solutions described in the foregoing embodiments or equivalent replacements may still be made to some or all technical features thereof. However, these modifications or replacements do not make the essence of the corresponding technical solutions depart from the scope of the technical solutions in the embodiments of this application.

What is claimed is:

1. A cooling medium distribution apparatus, comprising:
a first heat exchanger configured to condense a gaseous first cooling medium into a liquid first cooling medium, the first heat exchanger having a first runner and a second runner that are isolated from each other;
a second heat exchanger;
a liquid storage tank; and
a delivery pump, wherein
an input end of the first runner is configured to allow the gaseous first cooling medium to flow in, an output end of the first runner is in communication with an input end of the liquid storage tank, an output end of the liquid storage tank is configured to be in communication with an input end of the delivery pump, and an output end of the delivery pump is configured to allow the liquid first cooling medium to flow out;
the second runner is used for flowing of a second cooling medium to exchange heat with the first cooling medium in the first runner; and
the second heat exchanger has a third runner used for flowing of the second cooling medium, and the second heat exchanger is used to enable the second cooling medium in the third runner to exchange heat with the first cooling medium in the liquid storage tank, to reduce temperature of the first cooling medium in the liquid storage tank.

2. The cooling medium distribution apparatus according to claim 1, wherein the second heat exchanger further has a fourth runner used for flowing of the first cooling medium, and the fourth runner and the third runner are isolated from each other; and
an input end of the fourth runner is in communication with the output end of the liquid storage tank, and an output end of the fourth runner is in communication with the input end of the delivery pump.

3. The cooling medium distribution apparatus according to claim 2, wherein the second heat exchanger comprises a second housing and a second heat exchanger core;
the second housing has a second cavity, a second inlet and a second outlet are disposed on an inner wall of the second cavity, both the second inlet and the second outlet are in communication with the second cavity, the second inlet is used as the input end of the fourth runner, and the second outlet is used as the output end of the fourth runner; and
the second heat exchanger core has the third runner, the second heat exchanger core is located in the second cavity, and an outer wall of the second heat exchanger core and the inner wall of the second cavity jointly define the fourth runner.

4. The cooling medium distribution apparatus according to claim 3, wherein the second heat exchanger core comprises a second input tube, a second output tube, and a plurality of second helical tubes;
a first end of each second helical tube is in communication with the second input tube, a second end of each second helical tube is in communication with the second output tube, and the second input tube, the second output tube, and the plurality of second helical tubes jointly define the third runner;
the second input tube is configured to allow the second cooling medium to flow into each second helical tube; and
the second output tube is configured to allow the second cooling medium in the each second helical tube to flow out.

5. The cooling medium distribution apparatus according to claim 2, wherein the first heat exchanger, the liquid storage tank, the second heat exchanger, and the delivery pump are successively arranged from a top to a bottom in a gravity direction.

6. The cooling medium distribution apparatus according to claim 1, wherein the output end of the liquid storage tank is in communication with the input end of the delivery pump; and
the second heat exchanger is disposed in the liquid storage tank and disposed close to a bottom of the liquid storage tank.

7. The cooling medium distribution apparatus according to claim 6, wherein the first heat exchanger, the liquid storage tank, and the delivery pump are successively arranged from a top to a bottom in a gravity direction.

8. The cooling medium distribution apparatus according to claim 1, wherein the cooling medium distribution apparatus further comprises a supply apparatus;
an input end of the supply apparatus is configured to be in communication with an output end of the second runner or an output end of the third runner, and an output end of the supply apparatus is configured to be in communication with an input end of the second runner or an input end of the third runner; and
the supply apparatus is configured to deliver the second cooling medium to the second runner and the third runner.

9. A heat dissipation cabinet, comprising:
a cabinet; and
a cooling medium distribution apparatus accommodated in the cabinet, the cooling medium distribution apparatus comprising:
a first heat exchanger configured to condense a gaseous first cooling medium into a liquid first cooling medium, the first heat exchanger having a first runner and a second runner that are isolated from each other;
a second heat exchanger;
a liquid storage tank; and
a delivery pump, wherein
an input end of the first runner is configured to allow the gaseous first cooling medium to flow in, an output end of the first runner is in communication with an input end of the liquid storage tank, an output end of the liquid storage tank is configured to be in communication with an input end of the delivery pump, and an output end of the delivery pump is configured to allow the liquid first cooling medium to flow out;
the second runner is used for flowing of a second cooling medium to exchange heat with the first cooling medium in the first runner; and
the second heat exchanger has a third runner used for flowing of the second cooling medium, and the second heat exchanger is used to enable the second cooling medium in the third runner to exchange heat with the first cooling medium in the liquid storage tank, to reduce temperature of the first cooling medium in the liquid storage tank.

10. A server system, comprising:
an electronic device,
a first pipe,
a second pipe, and
a cooling medium distribution apparatus comprising:
a first heat exchanger configured to condense a gaseous first cooling medium into a liquid first cooling medium, the first heat exchanger having a first runner and a second runner that are isolated from each other;
a second heat exchanger;
a liquid storage tank; and
a delivery pump, wherein
an input end of the first runner is configured to allow the gaseous first cooling medium to flow in, an output end of the first runner is in communication with an input end of the liquid storage tank, an output end of the liquid storage tank is configured to be in communication with an input end of the delivery pump, and an output end of the delivery pump is configured to allow the liquid first cooling medium to flow out;
the second runner is used for flowing of a second cooling medium to exchange heat with the first cooling medium in the first runner; and
the second heat exchanger has a third runner used for flowing of the second cooling medium, and the second heat exchanger is used to enable the second cooling medium in the third runner to exchange heat with the first cooling medium in the liquid storage tank, to reduce temperature of the first cooling medium in the liquid storage tank; wherein
an input end of a first runner of the cooling medium distribution apparatus is in communication with a first opening of the electronic device by using the first pipe, and an output end of a delivery pump of the cooling medium distribution apparatus is in communication with a second opening of the electronic device by using the second pipe.

11. The heat dissipation cabinet according to claim 9, wherein the second heat exchanger further has a fourth runner used for flowing of the first cooling medium, and the fourth runner and the third runner are isolated from each other; and
an input end of the fourth runner is in communication with the output end of the liquid storage tank, and an output end of the fourth runner is in communication with the input end of the delivery pump.

12. The heat dissipation cabinet according to claim 11, wherein the second heat exchanger comprises a second housing and a second heat exchanger core;
the second housing has a second cavity, a second inlet and a second outlet are disposed on an inner wall of the second cavity, both the second inlet and the second outlet are in communication with the second cavity, the second inlet is used as the input end of the fourth runner, and the second outlet is used as the output end of the fourth runner; and
the second heat exchanger core has the third runner, the second heat exchanger core is located in the second cavity, and an outer wall of the second heat exchanger core and the inner wall of the second cavity jointly define the fourth runner.

13. The heat dissipation cabinet according to claim 12, wherein the second heat exchanger core comprises a second input tube, a second output tube, and a plurality of second helical tubes;
a first end of each second helical tube is in communication with the second input tube, a second end of each second helical tube is in communication with the second output tube, and the second input tube, the second output tube, and the plurality of second helical tubes jointly define the third runner;
the second input tube is configured to allow the second cooling medium to flow into each second helical tube; and
the second output tube is configured to allow the second cooling medium in the each second helical tube to flow out.

14. The heat dissipation cabinet according to claim 11, wherein the first heat exchanger, the liquid storage tank, the second heat exchanger, and the delivery pump are successively arranged from a top to a bottom in a gravity direction.

15. The heat dissipation cabinet according to claim 9, wherein the output end of the liquid storage tank is in communication with the input end of the delivery pump; and
the second heat exchanger is disposed in the liquid storage tank and disposed close to a bottom of the liquid storage tank.

16. The server system according to claim 10, wherein the second heat exchanger further has a fourth runner used for flowing of the first cooling medium, and the fourth runner and the third runner are isolated from each other; and
an input end of the fourth runner is in communication with the output end of the liquid storage tank, and an output end of the fourth runner is in communication with the input end of the delivery pump.

17. The server system according to claim 16, wherein the second heat exchanger comprises a second housing and a second heat exchanger core;
the second housing has a second cavity, a second inlet and a second outlet are disposed on an inner wall of the second cavity, both the second inlet and the second outlet are in communication with the second cavity, the second inlet is used as the input end of the fourth runner, and the second outlet is used as the output end of the fourth runner; and
the second heat exchanger core has the third runner, the second heat exchanger core is located in the second cavity, and an outer wall of the second heat exchanger core and the inner wall of the second cavity jointly define the fourth runner.

18. The server system according to claim 17, wherein the second heat exchanger core comprises a second input tube, a second output tube, and a plurality of second helical tubes;
a first end of each second helical tube is in communication with the second input tube, a second end of each second helical tube is in communication with the second output tube, and the second input tube, the second output tube, and the plurality of second helical tubes jointly define the third runner;
the second input tube is configured to allow the second cooling medium to flow into each second helical tube; and
the second output tube is configured to allow the second cooling medium in the each second helical tube to flow out.

19. The server system according to claim 16, wherein the first heat exchanger, the liquid storage tank, the second heat exchanger, and the delivery pump are successively arranged from a top to a bottom in a gravity direction.

20. The server system according to claim 10, wherein the output end of the liquid storage tank is in communication with the input end of the delivery pump; and
the second heat exchanger is disposed in the liquid storage tank and disposed close to a bottom of the liquid storage tank.
